(19) United States
(12) Patent Application Publication
(10) Pub. No.: US 2026/0265643 A1
(43) Pub. Date: Sep. 10, 2026

(54) ELECTRONIC DEVICE MANUFACTURING AQUEOUS SOLUTION, METHOD FOR PRODUCING RESIST PATTERN, AND METHOD FOR MANUFACTURING DEVICE

(71) Applicant: Merck Patent GmbH, Darmstadt (DE)

(72) Inventors: Hiroshi Yanagita, Shizuoka (JP); Maki Ishii, Shizuoka (JP); Kazuma Yamamoto, Shizuoka (JP); Ryota Sumi, Shizuoka (JP)

(21) Appl. No.: 19/658,298

(22) Filed: Apr. 24, 2026

Related U.S. Application Data
(63) Continuation of application No. PCT/EP2024/080003, filed on Oct. 24, 2024.

(30) Foreign Application Priority Data
Oct. 25, 2023 (JP) 2023-183317

(51) Int. Cl. C11D 1/22; C11D 1/14; C11D 3/34; C11D 3/43; G03F 7/039; G03F 7/20; H10P 50/00; H10P 50/24; H10P 70/00

(52) U.S. Cl. CPC C11D 1/22; C11D 1/14; C11D 3/3418; C11D 3/349; C11D 3/43; G03F 7/0392; G03F 7/2004; H10P 50/242; H10P 50/695; H10P 70/23; C11D 2111/22

(57) ABSTRACT

An electronic device manufacturing aqueous solution includes: an acid (A); a surfactant (B); and a solvent (C). The acid (A) has a pKa (H₂O) of 3.0 or less, and a number of carbon atoms contained in the acid (A) is 0 to 8 in one molecule. The surfactant (B) is substantially free from ethylene oxide repeating units and propylene oxide repeating units. The solvent (C) includes water (C-1). The electronic device manufacturing aqueous solution is a high-performance material that can be used in the nanotechnology process of semiconductor device manufacturing, for example, in the manufacturing process of semiconductor devices that control liquid crystal, quantum dot, or OLED displays formed on a substrate.

### CROSS-REFERENCE TO RELATED APPLICATION

This application is a Continuation under 35 USC § 111(a) of International Patent Application PCT/EP2024/080003 (filed on Oct. 24, 2024), which claims the benefit of Japanese Patent Application No. 2023-183317 (filed on Oct. 25, 2023). The entire contents of these applications are incorporated herein by reference in their entirety.

### TECHNICAL FIELD

The present invention relates to an electronic device manufacturing aqueous solution, a method for producing a resist pattern, and a method for manufacturing a device.

### BACKGROUND ART

In recent years, there is an increasing need for highly integrated LSIs, and pattern miniaturization is demanded. In order to meet these needs, lithography processes using short wavelength KrF excimer laser (248 nm), ArF excimer laser (193 nm), extreme ultraviolet radiation (EUV; 13 nm), X-rays, electron beams, or the like are being put into practical use. In order to deal with the miniaturization of resist patterns, a photosensitive resin composition used as a resist in microfabrication is also required to have properties for high resolution. Short-wavelength light exposure can form finer patterns but creates exceptionally fine structures and therefore has an issue of reduced yield such as fine pattern collapse.

Japanese Patent Application Publication No. 2012-198456 discloses that pattern collapse and the like are suppressed by a rinse solution containing a sulfonic acid compound and a nonionic surfactant having an alkyleneoxy group.

### SUMMARY OF INVENTION

An electronic device manufacturing aqueous solution includes: an acid (A); a surfactant (B); and a solvent (C). The acid (A) has a pKa (H₂O) of 3.0 or less, and a number of carbon atoms contained in the acid (A) is 0 to 8 in one molecule. The surfactant (B) is substantially free from an ethylene oxide repeating unit and a propylene oxide repeating unit. The solvent (C) includes water (C-1).

A method for manufacturing a device according to the present invention comprises the aforementioned method for producing a resist pattern.

### Advantageous Effects of Invention

By using the electronic device manufacturing aqueous solution according to the present invention, the following one or more effects can be expected.

The defects can be suppressed from occurring in a fine resist pattern; The resist pattern collapse can be suppressed from occurring in a fine resist pattern; A resist pattern is suppressed from being slimmed down due to application of the electronic device manufacturing aqueous solution; The exposure amount can be further reduced; The process latitude can be increased.

The present invention has been made based on the technical background as described above, and provides an electEmbodiments of the present invention will be described in detail below.

### BRIEF DESCRIPTION OF THE DRAWINGS

FIG. 1 is a schematic view illustrating a state of rinsing a resist wall.

### DETAILED DESCRIPTION OF THE INVENTION

Embodiments of the invention will be described in detail below.

### Definitions

In the present specification, the definitions and examples provided in this paragraph are used unless specifically stated otherwise.

The singular shall include the plural, and “a” or “the” means “at least one”. An element of a concept can be expressed by a plurality of types, and when an amount (e.g., mass % or mol %) thereof is described, the amount thereof means a sum of the plurality of types thereof.

“And/or” includes all combinations of elements, and also includes use of either one of the elements.

When a numerical range is indicated using “to” or “-”, both end points are included in the range, and the units are common. For example, 5 to 25 mol % means 5 mol % or more and 25 mol % or less.

Descriptions such as “C_{x-y}”, “Cₓ-C_{y}”, and “Cₓ” mean the number of carbons in a molecule or a substituent. For example, C₁₋₆ alkyl means an alkyl chain (such as methyl, ethyl, propyl, butyl, pentyl, or hexyl) having from 1 to 6 carbons.

When the polymer includes multiple types of repeating units, these repeating units create a copolymer. The copolymer may be any of an alternating copolymer, a random copolymer, a block copolymer, a graft copolymer, or a mixture thereof. When a polymer or a resin is represented by a structural formula, n, m, or the like written in parentheses represents the number of repetitions.

The unit of temperature used is Celsius temperature (degree Celsius). For example, 20 degrees means 20 degrees Celsius.

An additive refers to a compound itself that has that function (e.g., a base generator refers to a compound itself that generates a base). There may also be an embodiment in which the compound is dissolved or dispersed in a solvent and is added to a composition. As an embodiment of the present invention, such a solvent is preferably comprised as the solvent (C) or other component in the composition according to the present invention.

### Electronic Device Manufacturing Aqueous Solution

The electronic device manufacturing aqueous solution according to the present invention comprises an acid (A) (hereinafter, referred to as component (A) in some cases. The same applies to other components.), a surfactant (B) and a solvent (C). The acid (A) has a pKa (H₂O) of 3.0 or less, and a number of carbon atoms contained in the acid (A) is 0 to 8 in one molecule; the surfactant (B) is substantially free from ethylene oxide repeating units and propylene oxide repeating units; and the solvent (C) comprises water (C-1).

The electronic device manufacturing aqueous solution is used during a process of manufacturing electronic device. This solution simply needs to be used in a process of manufacturing electronic device, and may be removed or eliminated in the course of the process. Examples of the electronic device include display devices, LEDs, and semiconductor devices.

The electronic device manufacturing aqueous solution is, for example, a semiconductor manufacturing aqueous solution, preferably a semiconductor substrate fabricating aqueous solution (is more preferably a cleaning liquid for semiconductor substrate fabrication process; still more preferably a lithography cleaning liquid; even more preferably a resist pattern cleaning liquid).

As another embodiment of the present invention, the electronic device manufacturing aqueous solution is a rinse composition used for rinsing an exposed/developed resist pattern.

### (A) Acid

The pKa (H₂O) of the acid (A) used in the present invention is 3.0 or less, preferably 2 to −12, and more preferably −2 to −11.

The number of carbon atoms contained in the acid (A) is 0 to 8 in one molecule, preferably 1 to 8, and more preferably 2 to 8. The number of carbon atoms contained in the acid (A) in one molecule refers to all the number of carbon atoms contained in the acid (A), includes the number of carbon atoms in the functional group FG_{A}, and similarly includes the number of carbon atoms in Alkyl₁.

The acid (A) preferably contains 1 to 4 (more preferably 2 to 4) functional groups FG_{A}, and the FG_{A} is at least one selected from the group consisting of a sulfo group, a sulfate group, a sulfino group, a sulfite group, a sulfonimide group, and a carboxy group, and more preferably at least one selected from the group consisting of a sulfo group and a sulfonimide group.

The molecular weight of the acid (A) is preferably 80 to 800, more preferably 90 to 600, and still more preferably 150 to 400.

The molar volume of the acid (A) is preferably 25 to 500 m³/mol, more preferably 40 to 350 m³/mol, and still more preferably 60 to 270 m³/mol.

In a preferred embodiment the acid (A) is represented by Formula (A):

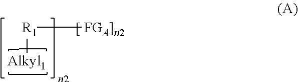

wherein,
n1 is 0, 1 or 2, and is preferably 1 or 2.
n2 is an integer of 1 to 4, and is preferably 1, 2 or 3. When n2=2, R₁ serving as a linker to bind two FG_{A}s is also a suitable embodiment;
   n3 is each independently an integer of 0 to 2, and is preferably 0 or 1. When n1=2,
   n3 represents the number of units per R₁. When n1=2, the maximum number of Alkyl₁ the acid (A) can possess per molecule is four;
   R₁ is each independently H, C₁₋₈ alkyl or C₅₋₈ aryl, and part or all of H in R₁ may be substituted or unsubstituted with F; and is preferably methyl, ethyl or phenyl;

When n1=2, R₁s may be bonded to each other and may or may not form a ring, although they preferably do not form a ring.

The FG_{A}s may be independently the same as or different from each other, and are each at least one selected from the group consisting of a sulfo group, a sulfate group, a sulfino group, a sulfite group, a sulfonimide group, and a carboxy group, and more preferably at least one selected from the group consisting of a sulfo group and a sulfonimide group.

Alkyl₁ is C₁₋₄ alkyl, and is preferably methyl.

When n1 is 0, a structure in which the FG_{A}s are directly connected to each other is formed. For example, oxalic acid should be read as being represented by Formula (A) in which n1=0, n2=2, and two FG_{A}s are both carboxy and directly connected to each other.

In one molecule of the acid (A), FG_{A} may be independently different from each other. The following compound is one of acids (A) represented by Formula (A). Here, n1=1, n2=3, n3=0, and R₁=phenyl. One of the FG_{A}s is a sulfonic acid and the other two are carboxylic acids.

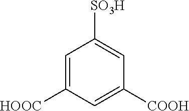 [SMILES: O=C(O)c1cc(C(=O)O)cc(S(=O)(=O)O)c1]

In a more preferred embodiment, the acid (A) is represented by Formulae (A-1) to (A-6), and still more preferably represented by Formula (A-1) or (A-5).

Formula (A-1) is below:

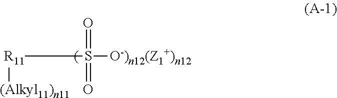

wherein,
n11 is 0, 1 or 2, and is preferably 1 or 2;
n12 is an integer of 1 to 4, and is preferably 1 or 2, and more preferably 1;
R₁₁ is H, C₁₋₈ alkyl or C₅₋₈ aryl, and is preferably H or phenyl, more preferably phenyl. Part or all of H in R₁₁ may be substituted or unsubstituted with F, but are preferably unsubstituted with F;
Alkyl₁₁ is C₁₋₄ alkyl or carboxy, and is preferably methyl or carboxy;
Z₁ is H, NH₄, Na, Li or K, and is preferably H.

### Examples of the Acid (A) Represented by Formula (A-1) Include the Following

p-toluenesulfonic acid, 5-sulfoisophthalic acid, trifluoromethanesulfonic acid, methanesulfonic acid, ethanesulfonic acid, propanesulfonic acid, butanesulfonic acid, benzenesulfonic acid, 4-fluorobenzenesulfonic acid, and 2,4-dimethylbenzenesulfonic acid.

Formula (A-2) is below:

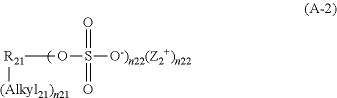

wherein,
n21 is 0 or 1, and is preferably 0.
n22 is an integer of 1 to 4, and is preferably 1.
R₂₁ is H, C₁₋₈ alkyl or C₅₋₈ aryl, and is preferably H, methyl or phenyl. Part or all of H in R₂₁ may be substituted or unsubstituted with F, but are preferably unsubstituted with F.
Alkyl₂₁ is C₁₋₄ alkyl, and is preferably methyl.
Z₂ is H, NH₄, Na, Li or K, and is preferably H.

### Examples of the Acid (A) Represented by Formula (A-2) Include the Following

sulfuric acid, methyl hydrogen sulfate, ethyl hydrogen sulfate, propyl hydrogen sulfate, butyl hydrogen sulfate, phenyl sulfate, and isopropyl hydrogen sulfate.

Formula (A-3) is below:

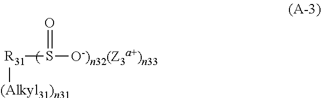

wherein,
n31 is 0 or 1, and is preferably 1;
n32 is an integer of 1 to 4, and is preferably 1 or 2, and more preferably 1;
a is 1 or 2, preferably 1;
n33 is n32/α;
R₃₁ is H, C₁₋₈ alkyl or C₅₋₈ aryl, and is preferably methyl or phenyl. Part or all of H in R₃₁ may be substituted or unsubstituted with F, but are preferably unsubstituted with F;
Alkyl₃₁ is C₁₋₄ alkyl, and is preferably methyl;
Z₃ is H, NH₄, Na, Li, K, Mg, Ca or Zn, and is preferably H.

### Examples of the Acid (A) Represented by Formula (A-3) Include the Following

sulfinic acid, p-toluenesulfinic acid, methanesulfinic acid, ethanesulfinic acid, propane-1-sulfinic acid, 2-methylpropane-2-sulfinic acid, and benzenesulfinic acid.

Formula (A-4) is below:

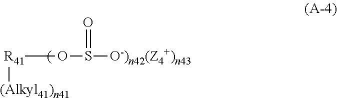

wherein,
n41 is 0 or 1, and is preferably 0;
n42 is an integer of 1 to 4, and is preferably 1;
R₄₁ is H, C₁₋₈ alkyl or C₅₋₈ aryl, and is preferably H or methyl. Part or all of H in R₄₁ may be substituted or unsubstituted with F, but are preferably unsubstituted with F;
Alkyl₄₁ is C₁₋₄ alkyl, and is preferably methyl;
Z₄ is H, NH₄, Na, Li or K, and is preferably H.

### Examples of the Acid (A) Represented by Formula (A-4) Include the Following

sulfurous acid, methyl bisulfite, ethyl bisulfite, and phenyl bisulfite.

Formula (A-5) is below:

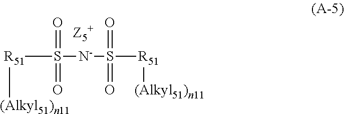

wherein,
n51 is 0 or 1, and is preferably 0;
R₅₁ is C₁₋₈ alkyl or C₅₋₈ aryl, and is preferably C₁₋₅ alkyl, more preferably methyl or ethyl. Part or all of H in R₅₁ may be substituted or unsubstituted with F;
Alkyl₅₁ is C₁₋₄ alkyl;
Z₅ is H, NH₄, Na, Li or K, and is preferably H.

### Examples of the Acid (A) Represented by Formula (A-5) Include

bis(trifluoromethanesulfonyl)imide, bis(methanesulfonyl)imide, bis(pentafluoroethanesulfonyl)imide, bis(1,1,2,2,3,3,3-heptafluoro-1-propanesulfonyl)imide, bi(1,1,2,2,3,3,4,4,4-nonafluoro-1-butanesulfonyl)imide, 4,4,5,5,6,6-hexafluorodihydro-4H-1,3,2-dithiazine 1,1,3,3-tetraoxide.

Formula (A-6) is below:

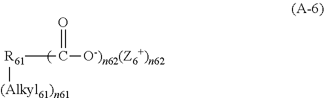

wherein,
n61 is 0 or 1, and is preferably 0;
n62 is an integer of 1 to 4, and is preferably 1 or 2;
R₆₁ is a single bond, H, C₁₋₈ alkyl or C₅₋₈ aryl, and is preferably a single bond or methyl. Part or all of H in R₆₁ may be substituted or unsubstituted with F, but are preferably unsubstituted with F;
Alkyl₆₁ is C₁₋₄ alkyl, and is preferably methyl;
Z₆ is H, NH₄, Na, Li or K, and is preferably H.

### Examples of the Acid (A) Represented by Formula (A-6) Include the Following

oxalic acid, trifluoroacetic acid, malonic acid, difluoromalonic acid, tetrafluorosuccinic acid, and phthalic acid.

The component (A) may be one type or a mixture of two or more types. The content of the component (A) is preferably 0.001 to 0.1 mass %, more preferably 0.002 to 0.07 mass %, still more preferably 0.003 to 0.05 mass %, and even more preferably 0.005 to 0.03 mass %, based on the total mass of the electronic device manufacturing aqueous solution.

### (B) Surfactant

The surfactant (B) used in the present invention is substantially free from ethylene oxide repeating units and propylene oxide repeating units. In the present invention, the wording “substantially free from ethylene oxide repeating units and propylene oxide repeating units” means that the percentage of the sum of the atomic weights of the ethylene oxide repeating units and of the propylene oxide repeating units in the molecular weight of the surfactant (B) is preferably 0 to 10%, more preferably 0 to 5%, and still more preferably 0%. The total number of carbons in one or a plurality of ethylene oxide repeating units and/or one or a plurality of proxylene oxide repeating units included in one molecule is 0 to 8, more preferably 0 to 6, and still more preferably 0 to 4. The surfactant (B) preferably does not contain an ethylene oxide repeating unit and a propylene oxide repeating unit (the total number of the aforesaid carbons is 0).

The surfactant (B) preferably does not have an alkyne (carbon-carbon triple bond) structure.

The number of carbon atoms contained in the surfactant (B) in one molecule is preferably 8 to 30, more preferably 9 to 25, and still more preferably 10 to 20.

The surfactant (B) has an effect of reducing surface tension. When a surface tension of an aqueous solution prepared by adding the surfactant (B) at a concentration of 500 ppm in water is compared with a surface tension of a liquid composed only of water, the surface tension of the former is reduced by preferably 50% or more and more preferably 60% or more as compared with that of the latter. The surface tension can be measured with a surface tensiometer using capillary rise method.

On the other hand, when a surface tension of an aqueous solution prepared by adding the acid (A) at a concentration of 500 ppm in water is compared with a surface tension of a liquid composed only of water, the acid (A) reduces the surface tension preferably by 10% or less, more preferably 3% or less, and still more preferably no decrease in the surface tension is shown by the acid (A).

The molecular weight of the surfactant (B) is preferably 100 to 1,000, more preferably 150 to 800, and still more preferably 180 to 600. The molar volume of the surfactant (B) is preferably 100 to 1,000 m³/mol, more preferably 150 to 800 m³/mol, and still more preferably 160 to 600 m³/mol.

Without being bound by theory, it is believed that when the aqueous solution of the present invention is used for cleaning a resist pattern, changes in shape or dimensions (more preferably, slimming down) of the resist pattern can be prevented owing to the inclusion of the acid (A) and the surfactant (B). In a preferred embodiment, the surfactant (B) comprises a monovalent anion moiety and a monovalent cation moiety, and the anion moiety is represented by Formula (B):

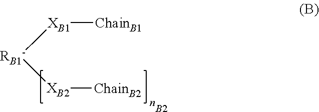

wherein,
R_{B1}⁻ is N⁻ or O⁻, and is preferably O⁻. As one of preferred embodiments of the present invention, “⁻” of R_{B1} is used for ionic bonding with a cation moiety. Unless otherwise stated, the other remaining bonds are bonded to hydrogen;
X_{B1} and X_{B2} are each independently —C(═O)— or —S(═O)₂—, and is preferably —S(═O)₂—;
n_{B2} is 0 or 1, and is preferably 0;
Chain_{B1} and Chain_{B2} are each independently a C₁₋₂₀ hydrocarbon group, and is preferably alkyl, phenyl-substituted alkyl, or alkyl-substituted phenyl.

Alkyl contained in the C₁₋₂₀ hydrocarbon group is linear, branched or cyclic alkyl.

When this hydrocarbon group contains an alkyl moiety, one or more methylenes present in this hydrocarbon group may be substituted or unsubstituted with —O—, and part or all of H present in this alkyl may be substituted or unsubstituted with F.

Chain_{B1} and Chain_{B2} may be bonded to each other and may or may not form a ring structure.

In this case, the monovalent cation moiety is selected from the group consisting of H⁺, NH₄⁺, Li⁺, Na⁺, and K⁺, and is preferably H⁺.

In a more preferred embodiment, the surfactant (B) is represented by Formula (B-1) or (B-2), and is more preferably represented by Formula (B-1).

Formula (B-1) is below:

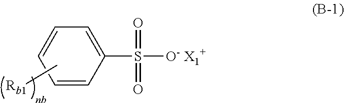

wherein
X₁⁺ is selected from the group consisting of H⁺, NH₄⁺, Li⁺, Na⁺ and K⁺, preferably is H⁺ or NH₄⁺, and still more preferably is H⁺;
nb is 1 or 2, and is preferably 1;
R_{b1} is C₁₋₂₀ alkyl, is preferably C₃₋₂₀ alkyl, and more preferably C₁₀₋₂₀ alkyl.

However, when nb is 2, R_{b1} may be the same as or different from each other, but the total number of carbon atoms is 20 or less. The alkyl of Rbi is preferably linear, branched or cyclic, more preferably linear or branched, and still more preferably linear.

Examples of Formula (B-1) include decylbenzenesulfonic acid, undecylbenzenesulfonic acid, dodecylbenzenesulfonic acid, tridecylbenzenesulfonic acid, tetradecylbenzenesulfonic acid, pentadecylbenzenesulfonic acid, hexadecylbenzenesulfonic acid, heptadecylbenzenesulfonic acid, octadecylbenzenesulfonic acid, nonadecylbenzenesulfonic acid, and the following compounds.

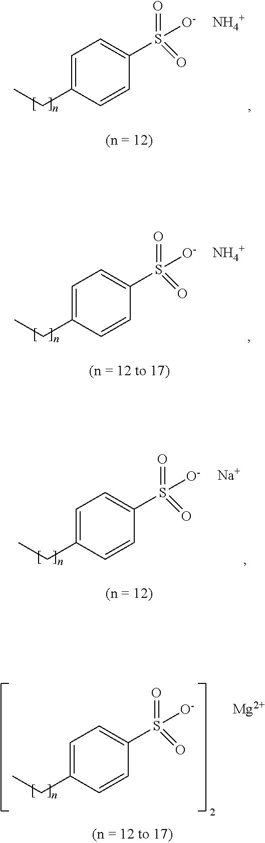

Formula (B-2) is below:

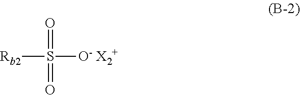

wherein
X₂⁺ is selected from the group consisting of H⁺, NH₄⁺, Li⁺, Na⁺ and K⁺, is preferably H⁺ or NH₄⁺, and still more preferably H⁺;
R_{b2} is C₃₋₂₀ alkyl, preferably C₈₋₂₀ alkyl, more preferably C₁₀₋₂₀ alkyl, still more preferably C₁₀₋₁₉ alkyl, and even more preferably C₁₃₋₁₉ alkyl. Preferably, the alkyl of R_{b2} is preferably linear, branched or cyclic, more preferably linear or branched, and still more preferably linear.

Examples of Formula (B-2) include decanesulfonic acid, undecanesulfonic acid, dodecanesulfonic acid, tridecanesulfonic acid, tetradecanesulfonic acid, pentadecanesulfonic acid, hexadecanesulfonic acid, heptadecanesulfonic acid, octadecanesulfonic acid, nonadecanesulfonic acid, and the following compounds.

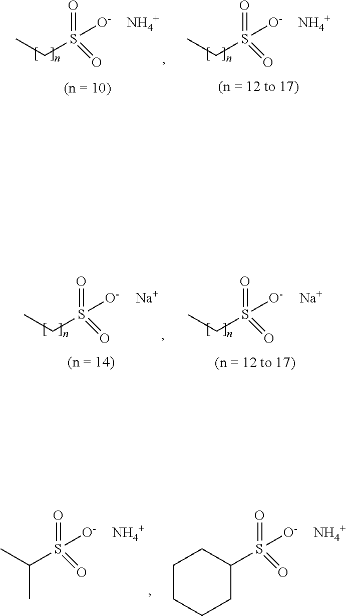

The component (B) may be one type or a mixture of two or more types.

The content of the component (B) is preferably 0.001 to 10 mass %, more preferably 0.005 to 5 mass %, and still more preferably 0.008 to 2 mass %, based on the total mass of the electronic device manufacturing aqueous solution.

As one of the effects in the electronic device manufacturing aqueous solution according to the present invention, mention may be made of suppression of defects after a resist pattern development owing to the inclusion of the component (A) as a specific acid and the component (B) as a specific surfactant. Without being bound by theory, the electronic device manufacturing aqueous solution is believed to have an effect of suppressing defects because the component (A) as a specific acid is similar to an acid generated from a photoacid generator contained in a resist composition and thus easily interacts with a resist residue, and after the interaction, the residue is easily floated and cleaned by the electronic device manufacturing aqueous solution, in which the component (B) is contained.

### Solvent (C)

The solvent (C) used in the present invention comprises water (C-1). The water (C-1) is preferably deionized water.

With the use of the solvent (C) in an electronic device manufacturing process, or in a semiconductor manufacturing process as a more preferable embodiment in views, the solvent (C) is preferably with few impurities. The impurity concentration in the solvent (C) is preferably 1 ppm or less (more preferably 100 ppb or less; still more preferably 10 ppb or less).

Water is preferably contained in an amount of preferably 90 to 100 mass % (more preferably 98 to 100 mass %; still more preferably 99 to 100 mass %; even more preferably 99.9 to 100 mass %) based on the mass of the solvent (C). As a preferred embodiment of the present invention, the solvent (C) is substantially composed only of water. However, an embodiment in which an additive is contained in the electronic device manufacturing aqueous solution according to the present invention with being dissolved and/or dispersed in a solvent other than water (e.g., a surfactant) is acceptable as a preferred embodiment of the present invention. As a more preferred embodiment of the present invention, the content of water contained in the solvent (C) is 100 mass %.

As a specific example of the solvent (C) other than water, suitable examples thereof include cyclohexanone, cyclopentanone, propylene glycol monomethyl ether (PGME), propylene glycol monoethyl ether, propylene glycol monopropyl ether, propylene glycol monobutyl ether, propylene glycol dimethyl ether, propylene glycol diethyl ether, propylene glycol 1-monomethyl ether 2-acetate (PGMEA), propylene glycol monoethyl ether acetate, propylene glycol monopropyl ether acetate, γ-butyrolactone, ethyl lactate, and a mixed solution thereof. These are preferable in terms of storage stability of the solution. Two or more types of these solvents can be mixed and used.

The content of the solvent (C) is preferably 80 to 99.998 mass %, more preferably 85 to 99.99 mass %, and still more preferably 89 to 99.98 mass %, based on the total mass of the electronic device manufacturing aqueous solution.

The content of water (C-1) is preferably 80 to 99.998 mass %, more preferably 85 to 99.99 mass %, and still more preferably 89 to 99.98 mass %, based on the total mass of the electronic device manufacturing aqueous solution.

The electronic device manufacturing aqueous solution according to the present invention is required to contain the aforesaid components (A), (B) and (C), but may contain an additional compound as necessary. Details will be described below. Note that the percentage of the component (if more than one components are contained, the sum thereof) other than the components (A) to (C) contained in the entire composition is preferably 0 to 10 mass % (more preferably 0 to 5 mass %; still more preferably 0 to 3 mass %; even more preferably 0.0001 to 1 mass %) based on the total mass of the electronic device manufacturing aqueous solution. An embodiment in which no components (0 mass %) other than the components (A) to (C) are contained in the electronic device manufacturing aqueous solution according to the present invention is also a preferred embodiment of the present invention.

### Additive (D)

The electronic device manufacturing aqueous solution according to the present invention can further comprise an additive (D). In the present invention, the additive (D) comprises a nitrogen-containing compound, another surfactant (a surfactant different from the component (B)), another acid (an acid different from the component (A)), another base, a disinfectant, an antibacterial agent, an antiseptic or an antifungal agent, and is preferably selected from a nitrogen-containing compound, another surfactant, another acid, another base, a disinfectant, an antibacterial agent, an antiseptic or an antifungal agent, and combinations thereof.

The content of the additive (D) is preferably 0.0001 to 10 mass %, more preferably 0.0001 to 0.1 mass %, and still more preferably 0.0002 to 0.001 mass %, based on the total mass of the electronic device manufacturing aqueous solution. An embodiment in which no additive (D) is contained is also a preferred embodiment of the present invention.

After having the components dissolved, the electronic device manufacturing aqueous solution according to the present invention can be filtered with a filter to remove impurities and/or insoluble matters.

### Method for Producing Resist Pattern

The present invention also provides a method for producing a resist pattern, in which the aforementioned electronic device manufacturing aqueous solution is used. A photosensitive resin composition (a resist composition) used in this method may be either a positive type or a negative type; and a positive type is more suitable. A typical method for producing a resist pattern, in which the electronic device manufacturing aqueous solution according to the present invention is applied, comprises the following steps of:
(1) applying a photosensitive resin composition to a substrate, with or without one or more intermediate layers interposed between the photosensitive resin composition and the substrate, to form a photosensitive resin layer;
(2) exposing the photosensitive resin layer to radiation;
(3) developing the exposed photosensitive resin layer; and
(4) cleaning the developed layer with the electronic device manufacturing aqueous solution.

### Details Will be Described Below.

First, a photosensitive resin composition is applied (e.g., layered) above a substrate, such as a silicon substrate or a glass substrate, which has been pretreated as necessary, to form a photosensitive resin layer. A known method can be used for layering, but a coating method such as spin coating is suitable. The photosensitive resin composition can be directly layered on the substrate, or can be layered with one or more intermediate layers (e.g., BARC) interposed between the photosensitive resin composition and the substrate. Alternatively, an antireflection film (e.g., TARC) may be layered above the photosensitive resin layer (on the side opposite to the substrate). A layer other than the photosensitive resin layer will be described later. The formation of the antireflection film above or below the photosensitive resin layer enables to improve the cross-sectional shape and the exposure margin.

Representative examples of the positive or negative photosensitive resin composition used in the method for producing a resist pattern according to the present invention comprise those comprising a quinonediazide-based photosensitive agent and an alkali-soluble resin, and chemically amplified photosensitive resin compositions. From a point of view of forming a high-resolution fine resist pattern, a chemically amplified photosensitive resin composition is preferable, and examples thereof include a chemically amplified PHS-acrylate hybrid EUV resist composition. These are more preferably positive photosensitive resin compositions.

Without being bound by theory, the inventors have contemplated as follows. The resist composition to be exposed to EUV is intended to form a finer resist pattern, but has a problem in which defects are more likely to occur in the formed resist pattern due to the properties (e.g., high hydrophobicity) of the resist composition. It is believed that the use of the aqueous solution of the present invention can prevent such defects and can clean the fine resist pattern.

As the quinonediazide-based photosensitive agent to be used in the aforementioned positive photosensitive resin composition that comprises a quinonediazide-based photosensitive agent and an alkali-soluble resin, examples thereof include 1,2-benzoquinonediazide-4-sulfonic acid, 1,2-naphthoquinonediazide-4-sulfonic acid, 1,2-naphthoquinonediazide-5-sulfonic acid, and esters or amides of these sulfonic acids, and examples of the alkali-soluble resin include polyvinyl phenols, polyvinyl alcohols, acrylic acid copolymers, and methacrylic acid copolymers.

Examples of the chemically amplified photosensitive resin composition comprise a positive chemically amplified photosensitive resin composition in which a compound (a photoacid generator) that generates an acid upon irradiated with radiation and a resin whose polarity is increased by the action of the acid generated from the photoacid generator and solubility in a developer solution changes between an exposed portion and an unexposed portion are comprised, and a negative chemically amplified photosensitive resin composition that comprises an alkali-soluble resin, a photoacid generator, and a crosslinking agent, in which crosslinking of the resin occurs by the crosslinking agent due to the action of the acid, and solubility in a developer solution changes between an exposed portion and an unexposed portion.

As the resin in which the polarity is increased by the action of the aforesaid acid and the solubility in a developer solution is changed between an exposed portion and an unexposed portion, example thereof include a resin in which a group that is decomposed by the action of the acid to generate an alkali-soluble group is included in the main chain or the side chain of the resin, or in both the main chain and the side chain of the resin. Typical examples thereof include a polymer in which an acetal group or a ketal group as a protecting group is introduced into a hydroxystyrene-based polymer (PHS) (e.g., Japanese Patent Application Publication No. H02-19847, etc.), and a similar polymer in which a t-butoxycarbonyloxy group or a p-tetrahydropyranyloxy group is introduced as a group for acidolysis (Japanese Patent Application Publication No. H02-209977, etc.).

The photoacid generator may be any compound that generates an acid upon irradiated with radiation, and examples thereof include onium salts such as diazonium salts, ammonium salts, phosphonium salts, iodonium salts, sulfonium salts, selenonium salts, and arsonium salts, organohalogen compounds, organometallic/organohalides, photoacid generators having an o-nitrobenzyl type protecting group, compounds that photodegrade to generate sulfonic acid, which are typified by iminosulfonates, etc., disulfone compounds, diazoketosulfone compounds, and diazodisulfone compounds. Alternatively, there can also be used a compound in which such group or compound that generates an acid when exposed to light is introduced into a main chain or a side chain of a polymer.

The aforesaid chemically amplified photosensitive resin composition may further comprise an acid-decomposable dissolution-inhibitive compound, a dye, a plasticizer, a surfactant, a photosensitizer, an organic basic compound, a compound that promotes solubility in a developer solution, etc., as necessary.

The aforementioned photosensitive resin composition is applied onto a substrate by, for example, an appropriate coating apparatus such as a spinner or a coater, or a coating method, and heated to remove the solvent in the photosensitive resin composition, to form a photosensitive resin layer. The heating temperature is preferably 70 to 150° C. (more preferably 90 to 150° C.). The heating time is preferably 10 to 600 seconds (more preferably 10 to 180 seconds; still more preferably 30 to 120 seconds).

In the method for producing a resist pattern according to the present invention, the presence of a film or a layer other than the photosensitive resin layer is also allowed. The substrate and the photosensitive resin layer may be not in direct contact with each other, and an intermediate layer may be interposed between the substrate and the photosensitive resin layer. The intermediate layer refers to a layer formed between the substrate and the photosensitive resin layer, and is also referred to as a bottom layer. Examples of the bottom layer include a substrate modification film, a planarization film, a bottom anti-reflective coating (BARC), an inorganic hard mask intermediate layer (silicon oxide film, silicon nitride film, and silicon oxynitride film), and an adhesion film. The planarization film is, for example, an SOC. Regarding the formation of the inorganic hardmask intermediate layer, Japanese Patent No. 5336306 can be referred to. The intermediate layer may include one layer or a plurality of layers. Alternatively, a top layer may be formed on the photosensitive resin layer. The top layer is, for example, a top anti-reflective coating (TARC).

For the layer configuration in a process for producing a resist pattern according to the present invention, a known method can be used in accordance with process conditions, and examples that may be mentioned include the following lamination configuration:
substrate/photosensitive resin layer
substrate/bottom layer/photosensitive resin layer
substrate/planarization film/photosensitive resin layer
substrate/planarization film/photosensitive resin layer/top layer
substrate/planarization film/BARC/photosensitive resin layer
substrate/planarization film/inorganic hardmask intermediate layer/photosensitive resin layer
substrate/planarization film/adhesion film/photosensitive resin layer
substrate/substrate modification layer/planarization film/photosensitive resin layer and
substrate/substrate modification layer/planarization film/adhesion film/photosensitive resin layer.

These layers can be cured by heating and/or exposing to light after application, or can be deposited by using a known method such as a CVD method. These layers can be removed by a known method (etching or the like), and can be patterned by using each upper layer as a mask.

A preferred embodiment of the present invention is that the photosensitive resin composition is directly applied on the substrate without interposing any intermediate layer. In another embodiment of the present invention, the TARC is not formed on the photosensitive resin layer.

As another embodiment of the present invention, a thickened resist pattern may be formed by forming a thickened layer on a photosensitive resin layer as in WO 2022/129015.

The photosensitive resin layer is exposed to light through a predetermined mask. When other layers are also included (TARC, etc.), they may be exposed to light together. The wavelength of radiation (light) used for exposure is not particularly limited, but exposure with light having a wavelength of 13.5 to 248 nm is preferable. Specifically, a KrF excimer laser (248 nm in wavelength), an ArF excimer laser (193 nm in wavelength), extreme ultraviolet radiation (EUV, 13.5 nm in wavelength), or the like can be used, and EUV is more preferable. These wavelengths have an allowable range of ±5%, preferably have an allowable range of ±1%. After the exposure, a post-exposure bake (PEB) can also be performed as necessary. The temperature of the PEB is preferably 70 to 150° C. (more preferably 80 to 120° C.) and the heating time is preferably 0.3 to 5 minutes (more preferably 0.5 to 2 minutes).

Next, development is performed with a developer solution. In the development of the method for producing a resist pattern according to the present invention, a 2.38 mass % (±1% is allowed) tetramethylammonium hydroxide (TMAH) aqueous solution is preferably used. Furthermore, a surfactant or the like can be added to this developer solution. The temperature of the developer solution is preferably 5 to 50° C. (more preferably 25 to 40° C.), and the development time is preferably 10 to 300 seconds (more preferably 20 to 60 seconds). As a development method, a known method such as puddle developing can be used.

As described above, the resist pattern of the present invention includes not only a resist pattern that is formed by exposing and developing a resist film but also a resist pattern that is coated with another layer or film and has an increased wall thickness.

The resist pattern (the developed photosensitive resin layer) created through the above-described steps is in an uncleaned condition. This resist pattern can be cleaned with the electronic device manufacturing aqueous solution according to the present invention. The time for allowing the electronic device manufacturing aqueous solution to contact with the resist pattern, that is, the processing time is preferably 1 second or more. The treatment temperature can also be freely chosen. The method for putting the electronic device manufacturing aqueous solution on the resist is also freely chosen, and for example, the resist can be contacted with the electronic device manufacturing aqueous solution by immersing a resist substrate into the electronic device manufacturing aqueous solution or by putting drops of the electronic device manufacturing aqueous solution onto the surface of a rotating resist substrate.

In the method for producing a resist pattern according to the present invention, before and/or after a cleaning process with the electronic device manufacturing aqueous solution, the resist pattern after development can be cleaned with another cleaning liquid. The other cleaning liquid is preferably water, and more preferably pure water (DW, deionized water, etc.). The cleaning before the cleaning process is useful for cleaning the developer solution attached to the resist pattern. The cleaning after the cleaning process is useful for cleaning the electronic device manufacturing aqueous solution. A preferred embodiment of the manufacturing method according to the present invention is a method in which pure water is poured into a developed resist pattern to clean the pattern while replacing a developer solution with pure water, and the electronic device manufacturing aqueous solution is poured into the resist pattern, while the pattern is immersed in pure water, to clean the pattern while replacing pure water with the electronic device manufacturing aqueous solution.

Cleaning by the electronic device manufacturing aqueous solution may be performed by a known method.

For example, the cleaning can be performed by immersing a resist substrate into the electronic device manufacturing aqueous solution or by putting drops of the electronic device manufacturing aqueous solution onto the surface of a rotating resist substrate.

These methods may be appropriately combined and carried out.

One of the conditions under which pattern collapse is prone to occur is a place where a spacing between the walls of a resist pattern is the narrowest. The condition becomes severe at the place where the walls of the resist pattern are parallel to each other. In the present specification, a distance of said spacing at which the spacing is the smallest on single circuit unit is defined as a minimum space size. Single circuit unit preferably becomes single semiconductor in a subsequent process. Also preferable is an embodiment in which single semiconductor includes single circuit unit in the horizontal direction and includes a plurality of circuit units in the vertical direction. As a matter of course, unlike the test sample, when the frequency of occurrence in places with narrow spacing between the walls, defects occur less frequently, and therefore the frequency of occurrence of defective products will decrease.

In the present invention, the minimum space size of the resist pattern in single circuit unit is preferably 5 to 30 nm, more preferably 10 to 20 nm, and still more preferably 10 to 17 nm.

### Method for Manufacturing Device

The method for manufacturing a device according to the present invention comprises a method for producing a resist pattern in which the electronic device manufacturing aqueous solution is used. Preferably, the method for manufacturing a device according to the present invention comprises etching a substrate by using the resist pattern produced by the aforementioned method as a mask to process the substrate. After the processing, the resist film is peeled off as necessary. Preferably, the device is a semiconductor.

In the manufacturing method of the present invention, the resist pattern is used as a mask for etching and thereby enabling to process the intermediate layer and/or the substrate. A known method such as dry etching or wet etching can be used for the etching, and dry etching is more suitable. For example, the resist pattern can be used as an etching mask to etch the intermediate layer, and the resultant intermediate layer pattern can be used as an etching mask to etch a substrate, thereby processing the substrate. Alternatively, the substrate can be directly etched while etching layers (e.g., an intermediate layer) below the resist layer by using the resist pattern as an etching mask. The processed substrate becomes, for example, a patterned substrate. The formed pattern can be used to form wiring on the substrate.

These layers can be preferably removed by dry etching with O₂, CF₄, CHF₃, Cl₂ or BCl₃, and O₂ or CF₄ can be preferably used.

As a preferred embodiment, the method of manufacturing a device according to the present invention further comprises forming wiring on the processed substrate.

### Stress Applied to Resist Wall

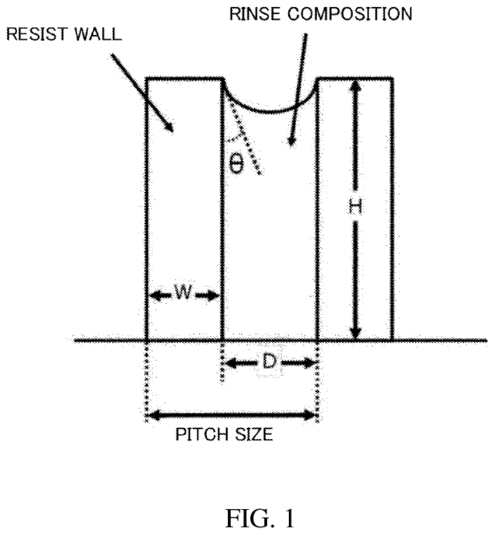

As described in Namatsu et al. Appl. Phys. Lett. 1995 (66) p 2655-2657 and schematically shown in FIG. 1, the stress applied to the wall during drying of rinse can be expressed by the following formula.

$${σ}_{m ax} = ( 6 γcosθ / D ) \times {( H / W )}^{2}$$

σₘₐₓ: Maximum stress applied to resist
γ: Surface tension of rinse
θ: Contact angle
D: Spacing between walls
H: Wall height
W: The width of the walls
   Their length can be measured by a known method, for example SEM photographs.

As can be seen from the equation set forth above, higher stress is caused when D is short or W is short. As used herein, “pitch size” refers to single unit with W and D, out of a resist pattern unit arrangement, as illustrated in FIG. 1.

This expression means that the finer the required resist pattern (the narrower the pitch size), the higher the stress applied to the resist pattern. In this manner, the finer the pattern becomes, the severer the conditions become, and the more improvement is required for an electronic device manufacturing aqueous solution (e.g., a rinse composition).

### EXAMPLES

The present invention will be described below by way of examples. Note that the embodiment of the present invention is not limited to these examples.

### Preparation of Electronic Device Manufacturing Aqueous Solution of Example 11

To deionized water are added p-toluenesulfonic acid as the component (A) so as to have a concentration of 300 ppm, and an alkylbenzenesulfonic acid mixture represented below as the component (B) so as to have a concentration of 600 ppm, and the mixture is stirred for 5 minutes. Complete dissolution is confirmed visually. This mixture is filtered (pore size=10 nm) to afford an electronic device manufacturing aqueous solution of Example 11.

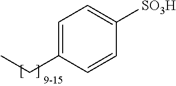

### Preparation of Electronic Device Manufacturing Aqueous Solution of Examples 12 to 19 and Comparative Examples 11 to 13

The electronic device manufacturing aqueous solution of each of Examples 12 to 19 and of Comparative Examples 11 and 12 is prepared by using the components (A) and (B) as described in Table 1 so as to have the concentrations described in Table 1 and in the same manner as in the aforementioned preparation of Example 11.

Comparative Example 13 is a filtrate of deionized water having nothing added.

TABLE 1

| | Component (A) | | Component (B) | | Performance |
|---|---|---|---|---|---|
| | | Added | | Added | evaluation |
| | Com- | amount | Com- | amount | for defects |
| | pound | ppm | pound | ppm | (1) |
| Example11 | A1 | 300 | B1 | 600 | 183 |
| Example12 | A1 | 300 | B2 | 500 | 217 |
| Example13 | A1 | 300 | B3 | 500 | 258 |
| Example14 | A1 | 300 | B4 | 600 | 236 |
| Example15 | A2 | 300 | B1 | 600 | 219 |
| Example16 | A3 | 490 | B1 | 600 | 219 |
| Example17 | A4 | 270 | B1 | 600 | 219 |
| Example18 | A1 | 100 | B5 | 900 | 325 |
| Example19 | A1 | 500 | B6 | 750 | 362 |
| Comparative | comp. A6 | 500 | B4 | 600 | 4538 |
| Example11 | | | | | |
| Comparative | comp. A7 | 500 | B1 | 600 | 3166 |
| Example12 | | | | | |
| Comparative | — | — | — | — | >10,000 |
| Example13 | | | | | |

In Tables 1 to 4:
A1: p-Toluenesulfonic acid
A2: 5-Sulfoisophthalic acid

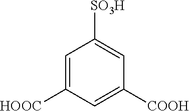 [SMILES: O=C(O)c1cc(C(=O)O)cc(S(=O)(=O)O)c1]

A3: Bis(trifluoromethanesulfonyl)imide

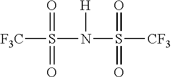 [SMILES: O=S(=O)(NS(=O)(=O)C(F)(F)F)C(F)(F)F]

A4: Bis(methanesulfonyl)imide

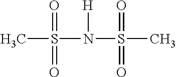

comp. A6: A compound having the following structure, wherein R^{a1} is methyl, R^{a2} is isobutyl, EO is ethylene oxide, PO is propylene oxide, r11, s11, r21, and s21 are integers satisfying each of the equations r11+r21=3.5 and s11+s21=0.

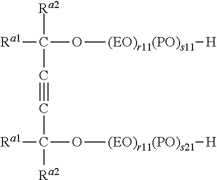

comp. A7: A compound having the structure set forth above, wherein Ral is methyl, R^{a2} is isobutyl, EO is ethylene oxide, PO is propylene oxide, r11, s11, r21, and s21 are integers satisfying each of the equations r11+r21=5 and s11+s21=2.
B1: Alkylbenzenesulfonic acid mixture (benzene moiety C₆+ alkyl moiety C₁₀₋₁₆)

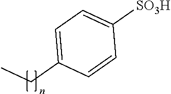

B2: Decanesulfonic acid

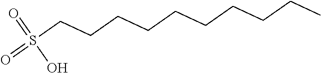

B3: Alkylsulfonic acid mixture (A mixture having the following structure with 13 to 18 carbon atoms),

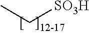

B4: Dodecylbenzenesulfonic acid

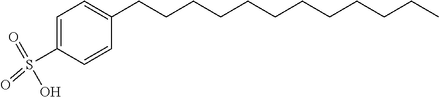 [SMILES: CCCCCCCCCCCCc1ccc(S(=O)(=O)O)cc1]

B5: 3,4-Dinonylbenzenesulfonic acid

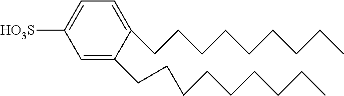 [SMILES: CCCCCCCCCc1ccc(S(=O)(=O)O)cc1CCCCCCCCC]

B6: 4-(1-Pentylheptyl)benzenesulfonic acid

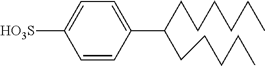 [SMILES: CCCCCCC(CCCCC)c1ccc(S(=O)(=O)O)cc1]

### Performance Evaluation for Defects (1)

A silicon substrate is treated with hexamethyldisilazane (HMDS) at 90° C. for 30 seconds. A PHS-acrylate-based chemically amplified resist for EUV is applied thereon by spin coating, followed by a heating on a hot plate at 110° C. for 60 seconds and thereby giving a resist film having a thickness of 35 nm. Thereafter, a 2.38 mass % TMAH aqueous solution as a developer solution is poured thereon, and then held for 30 seconds (Puddle development). In a state where a paddle of the developer solution is placed thereon, water starts to flow, the developer solution is replaced with water while the substrate is being rotated, and the substrate is stopped with a paddle of water placed thereon. Thereafter, while the electronic device manufacturing aqueous solution of Example 11 is poured onto the substrate with a paddle of water placed thereon, the substrate is cleaned while being rotated at a low speed for 30 seconds, and the water is replaced with the electronic device manufacturing aqueous solution of Example 11. This substrate is rotated at a high speed and dried to afford a cleaned resist film.

The surface of the cleaned resist film is observed with a defect inspection apparatus LS9110 (Hitachi High-Tech Corporation), and the number of foreign matters attached to the surface of the resist film is counted. The obtained results are as shown in Table 1.

An evaluation substrate is prepared for the electronic device manufacturing aqueous solution of each of Examples 11 to 19 and Comparative Examples 11 and 12, in the same manner as described above using the respective electronic device manufacturing aqueous solution, and the number of foreign matters is counted.

Comparative Example 13 is similar to Example 11 described above except that the substrate is spin-dried immediately after a paddle of water is formed thereon.

### Preparation of Electronic Device Manufacturing Aqueous Solution of Examples 21 to 29 and Comparative Example 21

An electronic device manufacturing aqueous solution of each Examples 21 to 29 is prepared in the same manner as in the aforementioned preparation example of Example 11 described above using the components (A) and (B) as shown in Table 2 so as to have the concentrations shown in Table 2.

Comparative Example 21 is a filtrate of deionized water having nothing added.

TABLE 2

| | Component (A) | | Component (B) | | | | |
|---|---|---|---|---|---|---|---|
| | | Added | | Added | Performance | Number of | Limit |
| | | amount | | amount | evaluation for | pattern | pattern |
| | Compound | ppm | Compound | ppm | defects (2) | collapses | size (nm) |
| Example21 | A1 | 300 | B1 | 600 | A | 0 | 12.9 |
| Example22 | A1 | 300 | B2 | 500 | A | 0 | 13.4 |
| Example23 | A1 | 300 | B3 | 500 | A | 0 | 13.2 |
| Example24 | A1 | 300 | B4 | 600 | A | 0 | 13.5 |
| Example25 | A2 | 300 | B1 | 600 | A | 0 | 13.1 |
| Example26 | A3 | 490 | B1 | 600 | A | 0 | 13.3 |
| Example27 | A4 | 270 | B1 | 600 | A | 0 | 13.2 |
| Example28 | A1 | 100 | B5 | 900 | A | 0 | 13.1 |
| Example29 | A1 | 500 | B6 | 750 | A | 0 | 13.2 |
| Comparative | — | — | — | — | Reference | 57 | 16.8 |
| Example21 | | | | | | | |

### Performance Evaluation for Defects (2)

A silicon substrate is treated with HMDS at 90° C. for 30 seconds. A PHS-acrylate-based chemically amplified resist for EUV is applied thereon by spin coating, followed by heating on a hot plate at 110° C. for 60 seconds to afford a resist film having a thickness of 35 nm. By using an EUV exposure apparatus (NXE: 3400, ASML), this substrate is exposed through a mask (18 nm lines/space 1:1) to light. Thereafter, PEB is performed on a hot plate at 110° C. for 60 seconds, and a 2.38 mass % TMAH aqueous solution as a developer solution is poured thereon, and then held for 30 seconds. Water starts to flow in a state where a paddle of the developer solution is placed on the substrate, the developer solution is replaced with water while the substrate being rotated, and the substrate is stopped with a paddle of water placed thereon. Thereafter, while the electronic device manufacturing aqueous solution of Example 21 is poured onto the substrate with a paddle of water placed thereon, the substrate is cleaned while being rotated at a low speed for 30 seconds, and the water is replaced with the electronic device manufacturing aqueous solution of Example 21. This substrate is rotated at a high speed and dried to afford a cleaned resist pattern.

The number of foreign matters attached to the surface of the cleaned resist pattern is counted with a defect inspection apparatus UVision4 (Applied Materials, Inc.), and the shape of the foreign matter is observed with a defect observation apparatus eDR7280 (KLA-Tencor Corporation). Defects are rated according to the following criteria. The obtained results are as shown in Table 2.
A: The number of defects is found to be less than 30% as compared with the number of foreign matters in Comparative Example 21.
B: The number of defects is found to be 30% or more and less than 100% as compared with the number of foreign matters in Comparative Example 21.
C: The number of defects is found to be 100% or more and less than 300% as compared with the number of foreign matters in Comparative Example 21.
D: All patterns are dissolved.

An evaluation substrate for the electronic device manufacturing aqueous solution of each of Examples 22 to 29 is prepared in the same manner as described above using the respective electronic device manufacturing aqueous solution, and evaluation is performed according to the aforementioned criteria.

Comparative Example 21 is similar to Example 21 described above except that the substrate is spin-dried immediately after a paddle of water is formed thereon.

### Number of Pattern Collapses

A cleaned resist pattern is obtained in the same manner as in the performance evaluation for defects (2).

The number of collapsed patterns of the cleaned resist pattern is counted using the defect inspection apparatus UVision4 and the defect observation apparatus eDR7280. The obtained results are as shown in Table 2.

### Limit Pattern Size

A silicon substrate is treated with HMDS at 90° C. for 30 seconds. A PHS-acrylate-based chemically amplified resist for EUV is applied thereon by spin coating, followed by heating on a hot plate at 110° C. for 60 seconds to afford a resist film having a thickness of 50 nm. This substrate is exposed through a mask (16 nm line/space 1:1) to light with an EUV exposure apparatus (NXE: 3400). At this time, the exposure amount is changed so that the resultant line width is changed. Thereafter, PEB is performed on a hot plate at 110° C. for 60 seconds, and a 2.38 mass % TMAH aqueous solution as a developer solution is poured thereon, and then held for 30 seconds. Water starts to flow in a state where a paddle of the developer solution is placed thereon, the developer solution is replaced with water while the substrate being rotated, and the substrate is stopped with a paddle of water placed thereon. Thereafter, while the electronic device manufacturing aqueous solution of Example 21 is poured onto the substrate with a paddle of water placed thereon, the substrate is cleaned while being rotated at a low speed for 30 seconds, and the water is replaced with the electronic device manufacturing aqueous solution of Example 21. This substrate is rotated at a high speed and dried to afford a cleaned resist pattern.

The cleaned resist pattern is observed with a SEM apparatus CG6300 (Hitachi High-Tech Corporation), and the line width and the presence or absence of pattern collapse are observed. The minimum line width at which no pattern collapse occurs is defined as a “limit pattern size”. The obtained results are as shown in Table 2.

The “limit pattern size” for the aqueous solution of Examples 22 to 29 is obtained in the same manner as described above by using the respective electronic device manufacturing aqueous solution.

Comparative Example 21 is similar to Example 21 described above except that the substrate is spin-dried immediately after a paddle of water is formed thereon. In this case, a pattern collapse is confirmed at a line width of 16.4 nm, while a pattern collapse is not confirmed at a line width of 16.8 nm, and hence the limit pattern size is determined to be 16.8 nm.

### Preparation of Electronic Device Manufacturing Aqueous Solution of Examples 31 to 39, Comparative Examples 31 and 32, and Reference Examples 31 and 32

An electronic device manufacturing aqueous solution of each of Examples 31 to 39 and of Comparative Examples 31 and 32 is prepared in the same manner as in the aforementioned preparation of Example 11 by using the components (A) and (B) as described in Table 3 so as to have the concentrations described in Table 3.

TABLE 3

| | Component (A) | | Component (B) | | | |
|---|---|---|---|---|---|---|
| | | Added | | Added | Optimal EUV | |
| | | amount | | amount | radiation dose | |
| | Compound | ppm | Compound | ppm | (mJ/cm²) | EL |
| Example31 | A1 | 300 | B1 | 600 | 86 | 9.5 |
| Example32 | A1 | 300 | B2 | 500 | 84 | 9.0 |
| Example33 | A1 | 300 | B3 | 500 | 86 | 9.0 |
| Example34 | A1 | 300 | B4 | 600 | 85 | 9.0 |
| Example35 | A2 | 300 | B1 | 600 | 82 | 9.5 |
| Example36 | A3 | 490 | B1 | 600 | 89 | 8.5 |
| Example37 | A4 | 270 | B1 | 600 | 83 | 9.5 |
| Example38 | A1 | 100 | B5 | 900 | 89 | 9.5 |
| Example39 | A1 | 500 | B6 | 750 | 88 | 8.5 |
| Comparative | comp. A6 | 500 | B4 | 600 | 97 | 6.5 |
| Example31 | | | | | | |
| Comparative | comp. A7 | 500 | B1 | 600 | 99 | 7.0 |
| Example32 | | | | | | |

### Optimal EUV Radiation Dose, and EL

A silicon substrate is treated with HMDS at 90° C. for 30 seconds. A PHS-acrylate-based chemically amplified resist for EUV is applied thereon by spin coating, and heated on a hot plate at 110° C. for 60 seconds to afford a resist film having a thickness of 35 nm. This substrate is exposed through a mask (18 nm line/space 1:1) to light using an EUV exposure apparatus (NXE: 3400). Thereafter, PEB is performed on a hot plate at 110° C. for 60 seconds, and a 2.38 mass % TMAH aqueous solution as a developer solution is poured thereon, and then held for 30 seconds. Water starts to flow in a state where a paddle of the developer solution is placed thereon, the developer solution is replaced with water while the substrate being rotated, and the substrate is stopped with a paddle of water placed thereon. Thereafter, while the electronic device manufacturing aqueous solution of Example 31 is poured onto the substrate with a paddle of water placed thereon, the substrate is cleaned while being rotated at a low speed for 30 seconds, and the water is replaced with the electronic device manufacturing aqueous solution of Example 31. This substrate is rotated at a high speed and dried to afford a cleaned resist pattern.

The EUV radiation dose at which the cleaned resist pattern becomes 18 nm (line/space 1:1) is defined as the optimum EUV radiation dose, and is described in Table 3.

The line width when the resist pattern is formed at the optimum EUV radiation dose is observed with the SEM equipment CG6300. The exposure amount is increased or decreased, and each exposure amount at which the line width changes by ±10% is obtained. The difference between these exposure amounts is divided by the optimum EUV radiation dose and this value is defined as exposure latitude (EL) and described in Table 3.

The “optimal EUV radiation dose” and “EL” for the electronic device manufacturing aqueous solution of each of Examples 31 to 39 and Comparative Examples 31 and 32 is obtained in the same manner as described above by using the respective electronic device manufacturing aqueous solution.

### Preparation of Electronic Device Manufacturing Aqueous Solution of Examples 41 and Comparative Examples 41 and 42

An electronic device manufacturing aqueous solution of each of Examples 41 and of Comparative Example 41 is prepared in the same manner as in the aforementioned preparation example of Example 11 by using the components (A) and (B) as described in Table 4 so as to have the concentrations described in Table 4.

Comparative Example 42 is a filtrate of deionized water having nothing added.

TABLE 4

| | Component (A) | | Component (B) | | |
|---|---|---|---|---|---|
| | | Added | | Added | Pattern |
| | | amount | | amount | size |
| | Compound | ppm | Compound | ppm | (nm) |
| Example41 | A1 | 300 | B1 | 600 | 19.3 |
| Comparative | A1 | 300 | — | — | 18.1 |
| Example41 | | | | | |
| Comparative | — | — | — | — | 20.0 |
| Example42 | | | | | |

### Change in Pattern Size

A silicon substrate is treated with HMDS at 90° C. for 30 seconds. A PHS-acrylate-based chemically amplified resist for EUV is applied thereon by spin coating, and heated on a hot plate at 110° C. for 60 seconds to afford a resist film having a thickness of 35 nm. This substrate is exposed through a mask (18 nm line/space 1:1) to light with an EUV exposure equipment (NXE: 3400). Thereafter, PEB is performed on a hot plate at 110° C. for 60 seconds, and a 2.38 mass % TMAH aqueous solution as a developer solution is poured thereon, and then held for 30 seconds. Water starts to flow in a state where a paddle of the developer solution is placed thereon, the developer solution is replaced with water while the substrate being rotated, and the substrate is stopped with a paddle of water placed thereon. This substrate is rotated at a high speed and dried to afford a cleaned resist pattern. The EUV radiation dose at which the resist pattern with a line width of 20.0 nm (line/space 1:1) is formed is defined as the reference radiation dose. This is referred to as Comparative Example 42.

In Examples 41 and 42, the same operation as in Comparative Example 42 is performed until the substrate is stopped with a paddle of water placed thereon. At this time, the exposure amount is the aforementioned reference radiation dose. Thereafter, while the electronic device manufacturing aqueous solution of Example 41 or Comparative Example 41 is poured onto the substrate with a paddle of water placed thereon, and the substrate is cleaned while being rotated at a low speed for 30 seconds, and the water is replaced with the electronic device manufacturing aqueous solution. This substrate is rotated at a high speed and dried to afford a cleaned resist pattern. The resulting pattern size is described in Table 4. It can be seen from this result that the formed resist pattern is slimmed down when the electronic device manufacturing aqueous solution does not contain the component (B).

### Reference Example: Surface Tension of Component (A)

Into deionized water is added p-toluenesulfonic acid as the component (A) so as to have a concentration of 500 ppm and thereby preparing an aqueous solution A. As an aqueous solution B is prepared a filtrate of deionized water to which nothing is added. The surface tension of each of the aqueous solutions is measured with a surface tensiometer using capillary rise method DG-1 (Surfgauge INSTRUMENTS). The obtained results for both are found to be 73 mN/m. It can be seen from this result that p-toluenesulfonic acid does not have an effect of changing the surface tension.

1) An electronic device manufacturing aqueous solution, comprising: an acid (A);
a surfactant (B); and a solvent (C), wherein
the acid (A) has a pKa (H₂O) of 3.0 or less, and a number of carbon atoms contained in the acid (A) is 0 to 8 in one molecule;
the surfactant (B) is substantially free from an ethylene oxide repeating unit and a propylene oxide repeating unit; and
the solvent (C) comprises water (C-1).

2) The electronic device manufacturing aqueous solution according to claim 1, wherein
the acid (A) contains one to four functional groups FG_{A}, and the FG_{A} is at least one selected from the group consisting of a sulfo group, a sulfate group, a sulfino group, a sulfite group, a sulfonimide group, and a carboxy group;
optionally, the acid (A) has a molecular weight of 80 to 800; or
optionally, the acid (A) has a molar volume of 25 to 500 m³/mol.

3) The electronic device manufacturing aqueous solution according to claim 2, wherein
the acid (A) is represented by Formula (A): 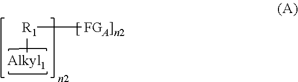
wherein
n1 is 0, 1 or 2;
n2 is an integer of 1 to 4;
n3 is each independently an integer of 0 to 2;
R₁ is each independently H, C₁₋₈ alkyl or C₅₋₈ aryl, and part or all of H in R₁ may be substituted or unsubstituted with F;
when n1=2, R₁s may be bonded to each other and may or may not form a ring;
the FG_{A} is as defined in claim 2, and each may be independently identical to or different from each other; and
Alkyl₁ is C₁₋₄ alkyl.

4) The electronic device manufacturing aqueous solution according to claim 1, wherein
the acid (A) is represented by Formulae (A-1) to (A-6): 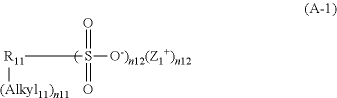
wherein
n11 is 0, 1, or 2;
n12 is an integer of 1 to 4;
R₁₁ is H, C₁₋₈ alkyl, or C₅₋₈ aryl, and part or all of H in R₁₁ may be substituted or unsubstituted with F;
Alkyl₁₁ is C₁₋₄ alkyl or carboxy; and
Z₁ is H, NH₄, Na, Li or K, 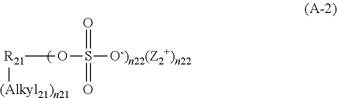
wherein
n21 is 0 or 1;
n22 is an integer of 1 to 4;
R₂₁ is H, C₁₋₈ alkyl, or C₅₋₈ aryl, and part or all of H in R₂₁ may be substituted or unsubstituted with F;
Alkyl₂₁ is C₁₋₄ alkyl; and
Z₂ is H, NH₄, Na, Li or K, 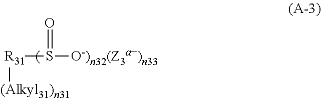
wherein
n31 is 0 or 1;
n32 is an integer of 1 to 4;
α is 1 or 2;
n33 is n32/α;
R₃₁ is H, C₁₋₈ alkyl, or C₅₋₈ aryl, and part or all of H in R₃₁ may be substituted or unsubstituted with F;
Alkyl₃₁ is C₁₋₄ alkyl; and
Z₃ is H, NH₄, Na, Li, K, Mg, Ca, or Zn, 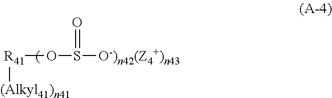
wherein
n41 is 0 or 1;
n42 is an integer of 1 to 4;
R₄₁ is H, C₁₋₈ alkyl, or C₅₋₈ aryl, and part or all of H in R₄₁ may be substituted or unsubstituted with F;
Alkyl₄₁ is C₁₋₄ alkyl; and
Z₄ is H, NH₄, Na, Li or K, 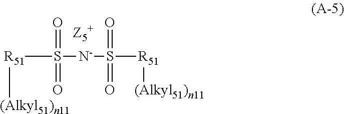
wherein
n51 is 0 or 1;
R₅₁ is C₁₋₈ alkyl or C₅₋₈ aryl, and part or all of H in R₅₁ may be substituted or unsubstituted with F;
Alkyl₅₁ is C₁₋₄ alkyl; and
Z₅ is H, NH₄, Na, Li or K, 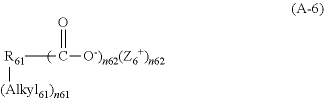
wherein
n61 is 0 or 1;
n62 is an integer of 1 to 4;
R₆₁ is a single bond, H, C₁₋₈ alkyl, or C₅₋₈ aryl, and part or all of H in R₆₁ may be substituted or unsubstituted with F;
Alkyl₆₁ is C₁₋₄ alkyl; and
Z₆ is H, NH₄, Na, Li or K.

5) The electronic device manufacturing aqueous solution according to claim 1, wherein the content of the acid (A) is 0.001 to 0.1 mass % based on a total mass of the electronic device manufacturing aqueous solution.

6) The electronic device manufacturing aqueous solution according to claim 1, wherein
when a surface tension of an aqueous solution prepared by adding the surfactant (B) at a concentration of 500 ppm in water (C-1) is compared with a surface tension of a liquid composed only of water (C-1), the surface tension of the former is reduced by 50% or more as compared with the surface tension of the latter, wherein
the surface tension is measured with a surface tensiometer using capillary rise method, wherein
optionally, when a surface tension of an aqueous solution prepared by adding the acid (A) at a concentration of 500 ppm in water (C-1) is compared with a surface tension of a liquid composed only of water (C-1), the acid (A) reduces the surface tension by 10% or less;
optionally, the surfactant (B) has a molecular weight of 100 to 1,000; or
optionally, the surfactant (B) has a molar volume of 100 to 1,000 m³/mol.

7) The electronic device manufacturing aqueous solution according to claim 1, wherein
the surfactant (B) comprises a monovalent anion moiety and a monovalent cation moiety, and the anion moiety is represented by Formula (B): 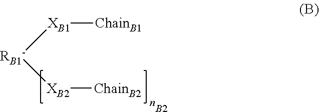
wherein
R_{B1}⁻ is N⁻ or O⁻;
X_{B1} and X_{B2} are each independently —C(═O)— or —S(═O)₂—;
n_{B2} is 0 or 1;
Chain_{B1} and Chain_{B2} are each independently a C₁₋₂₀ hydrocarbon group, and
when the hydrocarbon group contains an alkyl moiety, one or more methylenes present in the hydrocarbon group may be substituted or unsubstituted with —O—, and part or all of H present in the alkyl may be substituted or unsubstituted with F;
Chain_{B1} and Chain_{B2} may be bonded to each other and may or may not form a ring structure; wherein
the monovalent cation moiety is selected from the group consisting of H⁺, NH₄⁺, Li⁺, Na⁺ and K⁺; and
optionally, a number of carbon atoms contained in the surfactant (B) is 8 to 30 in one molecule.

8) The electronic device manufacturing aqueous solution according to claim 7, wherein
the C₁₋₂₀ hydrocarbon group is an alkyl, a phenyl-substituted alkyl, or an alkyl-substituted phenyl; and
optionally, an alkyl contained in the C₁₋₂₀ hydrocarbon group is a linear, branched or cyclic alkyl.

9) The electronic device manufacturing aqueous solution according to claim 1, wherein
the surfactant (B) is represented by Formula (B-1) or (B-2): 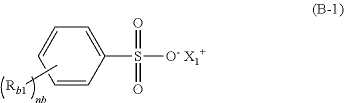
wherein
X₁⁺ is selected from the group consisting of H⁺, NH₄⁺, Li⁺, Na⁺ and K⁺;
nb is 1 or 2; and
R_{b1} is C₁₋₂₀ alkyl, 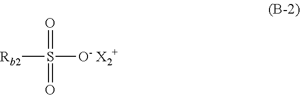
wherein
X₂⁺ is selected from the group consisting of H⁺, NH₄⁺, Li⁺, Na⁺ and K⁺; and
R_{b2} is C₃₋₂₀ alkyl.

10) The electronic device manufacturing aqueous solution according to claim 1, wherein
the content of the surfactant (B) is 0.001 to 10 mass % based on a total mass of the electronic device manufacturing aqueous solution;
optionally, the content of the solvent (C) is 80 to 99.998 mass % based on the total mass of the electronic device manufacturing aqueous solution; and
optionally, the content of the water (C-1) is 80 to 99.998 mass % based on the total mass of the electronic device manufacturing aqueous solution.

11) The electronic device manufacturing aqueous solution according to claim 1, further comprising: an additive (D), wherein
the additive (D) comprises a nitrogen-containing compound, another surfactant, another acid, another base, a disinfectant, an antibacterial agent, an antiseptic, or an antifungal agent; and
optionally, the content of the additive (D) is 0.0001 to 10 mass % based on a total mass of the electronic device manufacturing aqueous solution.

12) The electronic device manufacturing aqueous solution according to claim 1, which is an aqueous solution for manufacturing a semiconductor, wherein
optionally, the electronic device manufacturing aqueous solution is a semiconductor substrate fabricating aqueous solution;
optionally, the electronic device manufacturing aqueous solution is a cleaning liquid for semiconductor substrate fabrication process;
optionally, the electronic device manufacturing aqueous solution is a lithography cleaning liquid; or
optionally, the electronic device manufacturing aqueous solution is a resist pattern cleaning liquid.

13) A method for producing a resist pattern, comprising the following steps of:
(1) applying a photosensitive resin composition to a substrate, with or without one or more intermediate layers interposed between the photosensitive resin composition and the substrate, to form a photosensitive resin layer;
(2) exposing the photosensitive resin layer to radiation;
(3) developing the exposed photosensitive resin layer; and
(4) cleaning the developed layer with the electronic device manufacturing aqueous solution according to claim 1.

14) The method for producing a resist pattern according to claim 13, wherein
the photosensitive resin composition is a chemically amplified photosensitive resin composition, and optionally, the exposure is carried out using extreme ultraviolet radiation.

15) The method for producing a resist pattern according to claim 13, wherein a resist pattern in single circuit unit has a minimum space size of 5 to 30 nm.

16) A method for manufacturing a device, comprising the method for producing a resist pattern according to claim 13.

17) The method for manufacturing a device according to claim 16, further comprising etching a substrate by using as a mask the resist pattern produced by the method to process the substrate.

18) The method for manufacturing a device according to claim 16, further comprising forming wiring on the processed substrate.
